(19) United States
(12) Patent Application Publication
(10) Pub. No.: US 2013/0140078 A1
(43) Pub. Date: Jun. 6, 2013

(54) ELECTRONIC DEVICE AND JOINT

(71) Applicants: Chin-Ming Shih, Hsinchu City (TW); Jun-Chun Wong, Taipei City (TW)

(72) Inventors: Chin-Ming Shih, Hsinchu City (TW); Jun-Chun Wong, Taipei City (TW)

(73) Assignee: INDUSTRIAL TECHNOLOGY RESEARCH INSTITUTE, Hsinchu (TW)

(21) Appl. No.: 13/366,273

(22) Filed: Feb. 4, 2012

(30) Foreign Application Priority Data
Dec. 5, 2011 (TW) 100144646

(51) Int. Cl. H05K 7/14; H02G 15/32

(52) U.S. Cl. 174/535; 174/84 R

(57) ABSTRACT

An electronic device and a joint are provided. The electronic device includes a casing, an electronic element and the joint. The casing has a cable hole. The electronic element is disposed inside the casing. The joint includes a body, a waterproof and breathable film and a fastener. The body is fixed to the cable hole and has a breathable channel. The waterproof and breathable film is disposed at the breathable channel. The fastener is used for fastening a power cable to the body. The power cable passes through the fastener and the body and electrically connects the electronic element. The joint, a power cable and the casing form a waterproof and breathable chamber.

### CROSS-REFERENCE TO RELATED APPLICATION

This application claims the priority benefit of Taiwan application serial no. 100144646, filed on Dec. 5, 2011. The entirety of the above-mentioned patent application is hereby incorporated by reference herein and made a part of this specification.

### BACKGROUND

1. Technical Field

This disclosure relates to an electronic device and a joint, in particularly, relates to a waterproof and breathable electronic device and a joint.

2. Related Art

Powers saving topics are continuously put forward all over the world, and the products that are designed with green energy-saving features are gradually becoming mature. Nowadays, the power saving and carbon reduction has become the topic that all the countries put efforts on. The light-emitting diode (LED) illumination companies who are endeavoured to developing the green energy also starts thinking how to reduce the manufacturing cost. The LED is a new-generation power-saving light source as compared with the conventional light source and has the advantages of environmental friendly, power-saving and long lifespan features. The user may select the appropriate beam pattern according to different requirements of illumination brightness in different environments. Currently, the LED lamps are developed to be applied in an increasingly wide range of circumstances, and the LED lamps inevitably face the fate of greatly reducing the manufacturing cost. Therefore, the design of the lamp is an important issue for effectively reducing the lamp cost.

FIG. 1 is a partial schematic diagram illustrating an LED lamp in the prior art. Referring to FIG. 1, the LED lamp 100 currently available on the market adopts a waterproof design of a joint 120 of a power cable 110. The joint 120 functions to isolate the dust and water when the power cable 110 enters an isolated space in which dust and water must be prevented, so as to achieve the dust and water isolation function. In other words, the LED lamp 100 adopts the joint 120, thus forming an air-tight space inside a casing 130. However, the joint 120 is not breathable. In order to prevent the temperature changes to cause the thermal expansion and contraction of air inside the casing 130 and destroy the waterproof structure, a waterproof and breathable valve 140 is added on the casing 130, so as to provide a path for the air to enter and exit in the prerequisite of keeping the waterproof function. However, two holes 132 and 134 are drilled in the casing 130 in advance for disposing the joint 120 and the waterproof and breathable valve 140. Since the LED lamp 100 is developed in the trend of thin and light design, it is hard to provide enough space for disposing both the device joint 120 and the waterproof and breathable valve 140.

### SUMMARY

An electronic device is introduced herein, which achieves a waterproof and breathable purpose with a simple structure.

A joint is introduced herein, which is used for fixing a power cable and has waterproof and breathable functions.

The electronic device of this disclosure includes a casing, an electronic element and the joint. The casing has a cable hole. The electronic element is disposed inside the casing. The joint includes a body, a waterproof and breathable film and a fastener. The body is fixed to the cable hole and has a breathable channel. The waterproof and breathable film is disposed at the breathable channel. The fastener is used for fastening a power cable to the body. The power cable passes through the fastener and the body and electrically connects the electronic element. The joint, the power cable and the casing form a waterproof and breathable chamber.

The joint of this disclosure includes a body, a waterproof and breathable film and a fastener. The body has a breathable channel. The waterproof and breathable film is disposed at the breathable channel. The fastener is used for fastening a power cable to the body. The power cable passes through the fastener and the body.

In view of the above, in the electronic device and the joint of this disclosure, the joint may fix the power cable and is breathable and waterproof, and thus the electronic device is simplified.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a partial schematic diagram illustrating an LED lamp in the prior art.

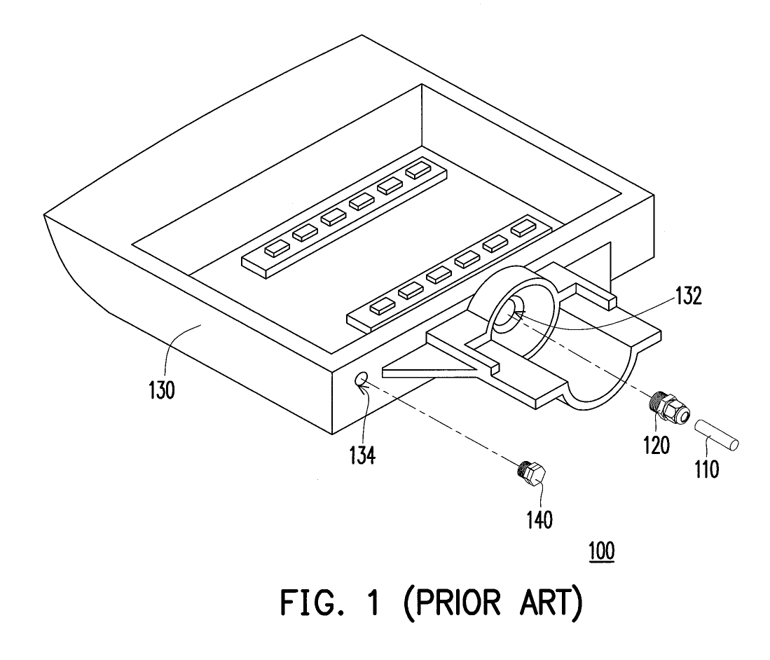

FIG. 2 is a partial exploded diagram illustrating an electronic device according to an embodiment of this disclosure.

FIG. 3 is a cross-sectional diagram illustrating a joint of FIG. 2 after assembled.

FIG. 4 is an exploded diagram illustrating a joint according to another embodiment of this disclosure.

FIG. 5 is a cross-sectional diagram illustrating the joint of FIG. 4 after assembled.

### DETAILED DESCRIPTION OF DISCLOSED EMBODIMENTS

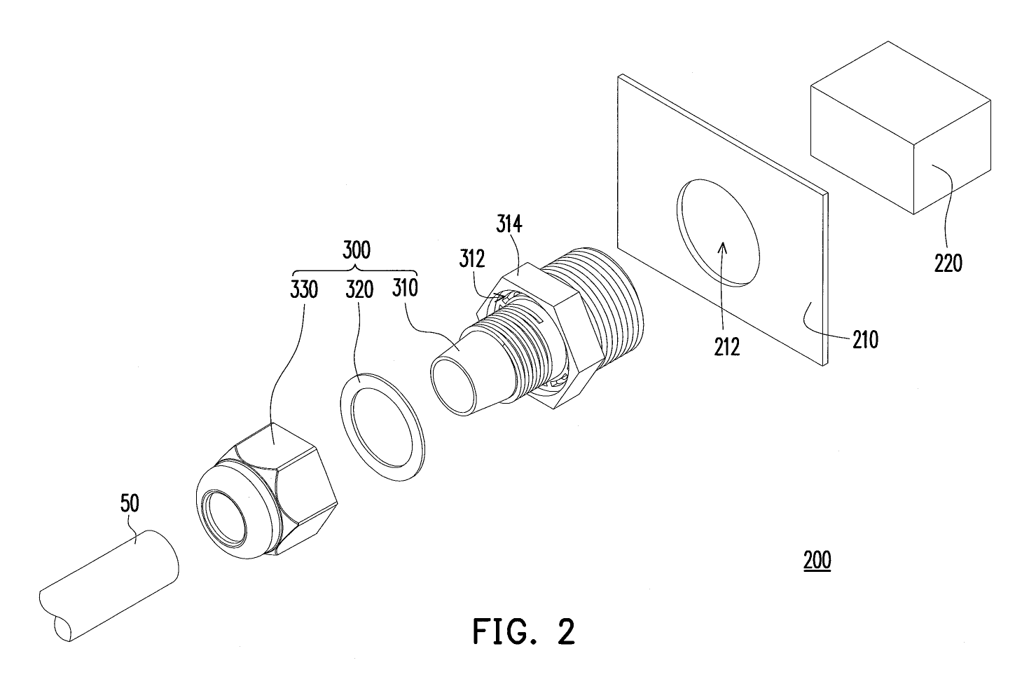

FIG. 2 is a partial exploded diagram illustrating an electronic device according to an embodiment of this disclosure. Referring to FIG. 2, the electronic device 200 of this embodiment includes a casing 210, an electronic element 220 and a joint 300. Since the design focus of the electronic device 200 of this embodiment is the joint 300, only a part of the casing 210 is shown and the electronic element 220 is represented by a block. Actually, the form of the casing 210 may be changed in accordance with different types of the electronic device 200 as long as the casing 210 has a cable hole 212 for installing the joint 300. The electronic element 220 is disposed in the casing 210. The electronic device 200 of this embodiment is for example a lamp, and the electronic element 220 is for example a light-emitting diode. However, the electronic device 200 may also be an outdoor transformer box or any electronic device that has the waterproof and breathable requirements.

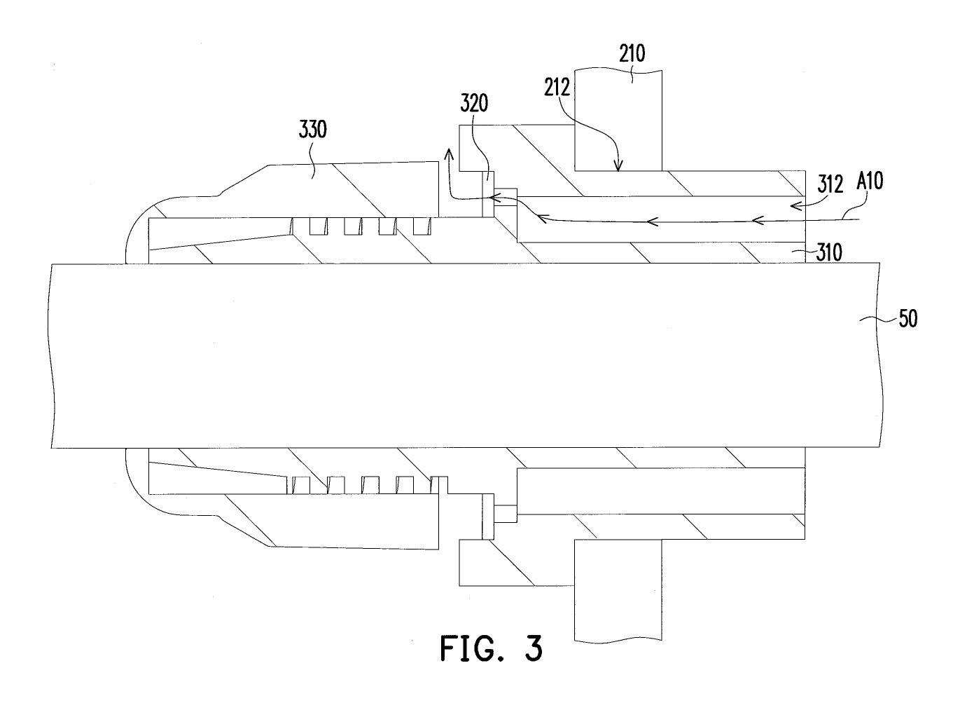

FIG. 3 is a cross-sectional diagram illustrating a joint of FIG. 2 after assembled. Referring to FIG. 2 and FIG. 3, the joint 300 of this embodiment includes a body 310, a waterproof and breathable film 320 and a fastener 330. The body 310 is fixed to the cable hole 212 and has a breathable channel 312. The waterproof and breathable film 320 is disposed at the breathable channel 312. The fastener 330 is used for fastening a power cable 50 to the body 310. For instance, when the fastener 330 is fastened to the body 310, one end of the body 310 close to the fastener 330 is pressed by the fastener 330 to clamp and fix the power cable 50. Definitely, the fastener 330 and the body 310 may be fitted to fix the power cable 50 in many ways that those skilled in the art may easily find, so the details will not be described herein. The power cable 50 passes through the fastener 330 and the body 310 and electrically connects the electronic element 220, so as to supply power to the electronic element 220. The joint 300 and the power cable 50 fully fill the cable hole 212, so the joint 300, the power cable 50 and the casing 210 may form a waterproof and breathable chamber, thereby protecting the electronic element 220 from the penetration of the outside moisture.

In the electronic device 200 of this embodiment, the casing 210 is only required to provide a cable hole 212 instead of additionally providing the breathable hole, so the assembly time is reduced and the cost is reduced. Moreover, the joint 300 provides an air path A10 that is formed by the waterproof and breathable film 320 and the breathable channel 312, so in addition to providing the path for adjusting the air when the temperature changes, the waterproof and breathable film 320 also prevents the penetration of moisture. Therefore, the joint 300 of this embodiment provides the functions such as fixing the power cable 50, waterproof and breathable functions.

The breathable channel 312 of this embodiment is for example embedded in a sidewall of the body 310. In some other embodiments, the breathable channel 312 may also communicate the space for the power cable 50 in a central part of the body 310, or the opening of the breathable channel 312 may be disposed at any appropriate position as long as the breathable function is achieved. Furthermore, the breathable channel 312 of this embodiment is constituted by a plurality of independent channels, but the breathable channel 312 may also be a single channel. In addition, the waterproof and breathable film 320 of this embodiment covers one side of the breathable channel 312 close to the fastener 330. However, the waterproof and breathable film 320 may also cover one side of the breathable channel 312 distal from the fastener 330, or the waterproof and breathable film 320 may also be disposed in the breathable channel 312. In this embodiment, the fastener 330 and the body 310 are screw-fitted, but the fastener 330 and the body 310 may also be fitted in other ways.

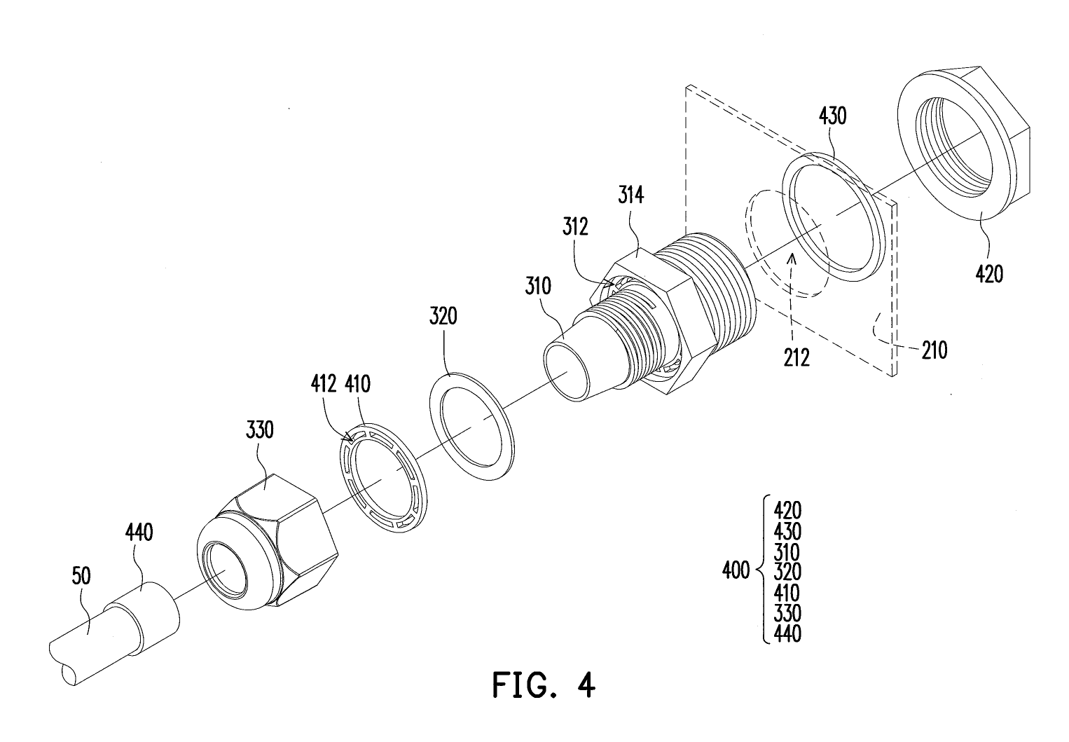

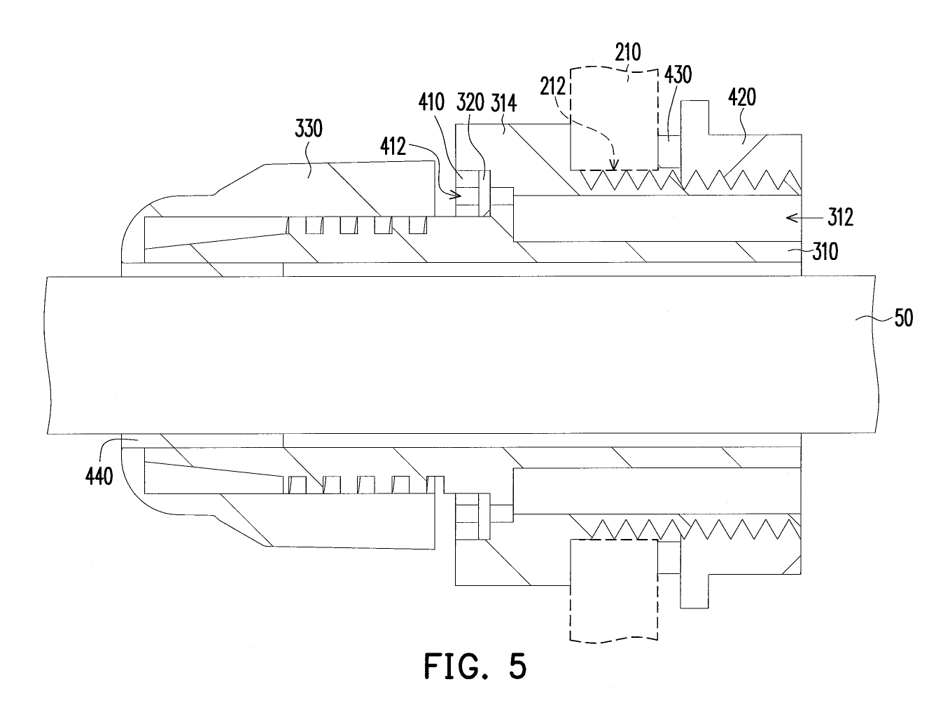

FIG. 4 is an exploded diagram illustrating a joint according to another embodiment of this disclosure. FIG. 5 is a cross-sectional diagram illustrating the joint of FIG. 4 after assembled. Referring to FIG. 4 and FIG. 5, the joint 400 of this embodiment is similar to the joint 300 of FIG. 2, and only the difference is described herein. The joint 400 of this embodiment further includes a pressing ring 410, a nut 420 and a washer 430. The pressing ring 410 is disposed at the body 310 to fix the waterproof and breathable film 320. The pressing ring 410 has a breathable hole 412 corresponding to the breathable channel 312. The pressing ring 410 of this embodiment has a plurality of breathable holes 412. The nut 420 of this embodiment is screw-fitted to one end of the body 310 distal from the fastener 330, that is, screw-fitted to one end of the body 310 located inside the casing 210. The body 310 has a stopping portion 314. A portion of the casing 210 around the cable hole 212 is clamped between the nut 420 and the stopping portion 314. In some other embodiments, the body 310 may be fixed to the casing 210 and meets the waterproof requirements in other designs, for example, a waterproof tape is wrapped around the body 310, which is not limited to the screw fastening. Furthermore, the washer 430 of this embodiment is disposed between the portion of the casing 210 around the cable hole 212 and the nut 420. The washer 430 ensures sealing the gap between the casing 210 and the nut 420 to achieve the waterproof purpose. The joint 400 of this embodiment further includes an elastic sleeve 440 sheathed on the power cable 50 and located between the power cable 50 and the body 310. The elastic sleeve 440 is used to ensure sealing the gap between the power cable 50 and the body 310. Likewise, the elastic sleeve 440 may also be applied in the embodiment of FIG. 2.

In view of the above, in the electronic device and the joint of this disclosure, the joint may be used for fixing the power cable and has the breathable channel and the waterproof and breathable film so as to provide both the waterproof and breathable functions, so that the electronic device is simplified to reduce the assembly time and the cost.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An electronic device, comprising:
a casing, having a cable hole;
an electronic element, disposed in the casing;
a joint, comprising:
a body, fixed to the cable hole and having a breathable channel;
a waterproof and breathable film, disposed at the breathable channel; and
a fastener, used for fastening a power cable to the body, wherein the power cable passes through the fastener and the body and electrically connects the electronic element, and the joint, the power cable and the casing forms a chamber.

2. The electronic device according to claim 1, wherein the breathable channel is embedded in a sidewall of the body.

3. The electronic device according to claim 1, wherein the waterproof and breathable film covers one side of the breathable channel close to the fastener.

4. The electronic device according to claim 1, wherein the fastener and the body are screw-fitted.

5. The electronic device according to claim 1, wherein the joint further comprises a pressing ring disposed at the body to fix the waterproof and breathable film, wherein the pressing ring has a breathable hole corresponding to the breathable channel.

6. The electronic device according to claim 1, wherein the joint further comprises a nut screw-fitted to one end of the body located in the casing, the body has a stopping portion, and a portion of the casing around the cable hole is clamped between the nut and the stopping portion.

7. The electronic device according to claim 6, wherein the joint further comprises a washer disposed between the portion of the casing around the cable hole and the nut.

8. The electronic device according to claim 1, further comprises an elastic sleeve sheathed on the the power cable and located between the power cable and the body.

9. The electronic device according to claim 1, wherein the electronic element is a light-emitting diode.

10. A joint, comprising:
a body, having a breathable channel;
a waterproof and breathable film, disposed at the breathable channel; and
a fastener, used for fastening a power cable to the body, wherein the power cable passes through the fastener and the body.

11. The joint according to claim 10, wherein the breathable channel is embedded in a sidewall of the body.

12. The joint according to claim 10, wherein the waterproof and breathable film covers one side of the breathable channel close to the fastener.

13. The joint according to claim 10, wherein the fastener and the body are screw-fitted.

14. The joint according to claim 10, further comprising a pressing ring disposed at the body to fix the waterproof and breathable film, wherein the pressing ring has a breathable hole corresponding to the breathable channel.

15. The joint according to claim 10, further comprising a nut screw-fitted to one end of the body distal from the fastener, wherein the body has a stopping portion, and the nut and the stopping portion collaboratively clamp a casing.

16. The joint according to claim 15, further comprising a washer disposed between the casing and the nut.

17. The joint according to claim 10, further comprising an elastic sleeve sheathed on the power cable and located between the power cable and the body.
